(19) United States
(12) Patent Application Publication
(10) Pub. No.: US 2008/0085834 A1
(43) Pub. Date: Apr. 10, 2008

(54) Superconductive circuits with efficient method

(76) Inventor: James Scott Hacsi, Pueblo, CO (US)

Correspondence Address: JAMES SCOTT HACSI, 13 DARTMOUTH AVENUE, PUEBLO, CO, 81005, US

(21) Appl. No.: 11/545,656

(22) Filed: Oct. 10, 2006

(51) Int. Cl. H01L 39/24

(52) U.S. Cl. 505/100

(57) ABSTRACT

Circuits exhibiting very low electrical resistance or superconductivity are provided as well as a method for transmitting, storing, or otherwise using electric energy more effectively and efficiently for providing powerful electromagnets for motors and generators, for transmitting electric power with few losses, or for making energy-storage devices with a high energy-density.

### CROSS-REFERENCE TO RELATED APPLICATIONS

Not applicable

### STATEMENT REGARDING FEDERALLY SPONSORED RESEARCH

Not applicable

### SEQUENCE LISTING OR PROGRAM

Not applicable

### BACKGROUND OF THE INVENTION

1. Field of the Invention

The present invention relates to superconductors, superconductive circuits, and electrical superconductive processes. More specifically, this invention relates to high-temperature superconductors and electrical superconductive processes occurring near normal room or ambient temperatures.

2. Description of Prior Art

There is an overwhelming and unmet need for electrical conductors with minimal electrical resistance for reducing electric power transfer losses. Superconductivity, or the loss of all resistance to electric current flow, is a well-known phenomenon that is limited by the tremendous cooling requirements for keeping a superconductor in a superconducting state at very cold temperatures. The quest continues to find superconductors that are superconductive at temperatures close to room or ambient temperatures. Researchers have recently discovered that the addition of certain nanoparticles less than 100 nanometers in size, when added to water, oil, or glycol mixtures, results in a nanofluid (a colloid with nanoparticles) that exhibits a substantial rise in thermal conductivity. In U.S. Pat. No. 6,221,275 (Choi, et al., 2001), a method is disclosed for producing nanocrystalline particles of such substances as copper, copper oxide, or aluminum oxide. The nanocrystalline particles are then dispersed in fluids such as deionized water, ethylene glycol, or oil for the purpose of enhancing heat transfer in those fluids. In U.S. Pat. No. 6,695,974 (Withers, et al., 2004), a heat transfer agent is disclosed as, “a complex comprising a body of heat transfer fluid, for example, ethylene glycol or water, having suspended therein carbon nanoparticles in a quantity sufficient to enhance the thermal conductivity of the body of heat transfers fluid, per se.” Neither Choi nor Withers disclose a fluid, however, of any kind, which contains nanoparticles, of any kind, that exhibits an anomalous increase in electrical conductivity; but, it is commonly known that materials exhibiting high thermal conductivity will most often also exhibit high electrical conductivity! In any case, Choi, Withers, and their associates failed to provide low-resistance electrical paths, circuits, and closed-loops containing their nanofluids because they must have simply overlooked the possibility of an anomalous increase in electrical conductivity that accompanies an anomalous increase in thermal conductivity. Some known inventions disclose and describe either supposed superconductive or superconducting circuits and methods, or else an apparatus that is superconductive, but such inventions must utilize cryogenic or cooling means to lower the temperature to make a circuit or device superconductive. Nothing novel in those inventions is introduced to create a superconductive “effect” in a conductor or a circuit other than what was accomplished previously by exposing the circuit or superconductor to extremely low temperatures. Certain inventions, such as disclosed in U.S. Pat. No. 4,082,991 (Constant, 1978), U.S. Pat. No. 5,532,638 (Kubo, et al., 1996), and U.S. Pat. No. 5,682,304 (Shteynberg, 1997), all describe methods of introducing, storing, or retrieving energy into or from cooled superconductors or superconductive circuits, but again, there is nothing introduced in those patent-specifications that hint of a superconductor or superconductive circuit that becomes superconducting with a novel “effect” without being cooled to extremely low temperatures.

3. Objects and Advantages

It would therefore be advantageous to use nanofluids with the correct concentration of nanoparticles dispersed in another fluid or medium to provide electrical paths, closed-loops, or circuits with minimal or zero resistance to electric current flow at ambient or room temperatures. In doing so, benefit would be taken of an anomalous increase in electrical conductivity that accompanies the observed anomalous increase in thermal conductivity in certain nanofluids. In words, new uses and purposes for nanofluids, such as those discovered and produced by Choi, Withers, and their associates, are contemplated by the present invention where closed-loops or circuits containing those mentioned nanofluids of Choi, Withers, and associates exhibit extremely low electrical resistance or are superconductive. It would also be advantageous to use colloids of any kind, including nanofluids, containing highly-charged, mutually-repelling conductive nanoparticles dispersed in a dispersing medium to provide electrical paths, closed-loops, or circuits with minimal or zero resistance to electric current flow at ambient or room temperatures. The nanoparticles comprising colloids of this nature, however, would be given an electric-charge that is produced and delivered by some man-made method or device.

Accordingly, certain objects and advantages of superconductors with superconductivity at room or ambient temperatures are:
(a) to provide a means for transferring electric power over long distances with few losses;
(b) to provide powerful electromagnets requiring minimal energy consumption for use in electric motors, generators, or for containing nuclear fusion reactions;
(c) to provide electric energy storage devices where electric current flow can be sustained indefinitely;
(d) to reduce our country's dependence on foreign oil and improve our national security.

### SUMMARY

In accordance with the present invention, superconductive circuits with improved electrical conductivity or superconductivity at room temperatures are provided. It has already been experimentally proven that nanofluids with the correct concentration of nanoparticles dispersed in another fluid or medium exhibit high thermal conductivity. The present invention exploits the fact that high electrical conductivity almost invariably occurs in matter that exhibits high thermal conductivity. Low-resistance electrical paths, circuits, and closed-loops are then contemplated that can result in the making of strong electromagnets with minimal power consumption for making powerful motors and efficient generators. Energy storage rings and devices for storing electric energy can also be devised, as well as superconductive networks with minimal losses for the long-distance transmission of electric power.

### Operational Theory

If there are a large number of free-electrons present in a material, the Wiedemann-Franz Law predicts fairly accurately a rise in electrical conductivity when there is a corresponding rise in thermal conductivity as long as the Lorentz number remains constant at a particular temperature. Free electrons, for example, in a metal's lattice interact with the lattice vibrations (called ‘phonons’) thereby picking up energy. When an electric field is applied, the electrons carry this energy and hence they transport both an electrical charge and heat. A direct relationship would understandably exist between electrical conductivity and thermal conductivity as long as the electron contribution is much higher than the phonon contribution. In the opposite case, where there are few free-electrons present, phonons can still transport heat (since it is the only transport mechanism in insulators). However, with a higher phonon contribution, it would then seem somewhat logical that a transport-mechanism can exist where phonons also transfer electrical charge. Moreover, if such a transport-mechanism exists for transporting or transferring electric charge in an insulator, then there is good reason to believe the charge-transport mechanism will work much better in a conductor if certain conditions are satisfied—even to the point of making the conductor superconductive! Since the increase in thermal conductivity in a nanofluid is currently regarded as “anomalous”, the effect deviates from what is normally expected. There is no way to be certain at this point, that improved heat-transfer in a nanofluid is accomplished by free-electrons, which would cast doubt on the reliability of the Wiedemann-Franz Law in predicting a rise in electrical conductivity that accompanies the observed rise in thermal conductivity. However, there is also no reason to be certain an even larger increase in electrical conductivity couldn't occur for the same increase in thermal conductivity, since the method of heat and electric-charge transport in a nanofluid is still unknown. The argument will most-likely continue; but all that's really important is what is actually observed. An answer to the question of what the heat-transport mechanism is in a nanofluid, however, may be obtained by first explaining the method of the present invention for increasing electrical conductivity in a colloid (which includes the nanofluids of Choi and Withers) even to the point where superconductivity occurs.

Colloidal particles dispersed in a solution can be electrically charged due to their ionic characteristics and dipolar attributes. A charged particle dispersed in a solution can also be surrounded by oppositely charged ions called the fixed-layer, and outside the fixed-layer there are varying compositions of ions of opposite polarities, forming a cloud-like area. This area is called the diffuse double-layer, and the whole area is electrically neutral. Zeta potential is considered to be the electric potential of this inner area including a conceptual “sliding surface”. As this electric potential approaches zero, particles tend to aggregate. It can then be assumed that if no external electric field is applied for causing movement of the charged particles in the colloid toward an electrode (electrophoresis), the particles will not aggregate due to their similar electric charge. The dispersed particles will most certainly arrange themselves into a lattice structure to minimize energy exchange, and the colloidal system will remain stable, if and only if, the coloumbic repulsion arising from the net charge on the surface of the particles remains greater than the Van der Waals force between those same particles. So, the higher the absolute zeta potential, the stronger the coloumbic repulsion between the particles, and therefore the lesser the impact of the Van der Waals force on the colloid. The lattice structure in a colloid due to electrically-charged particles loosely resembles the lattice arrangement of atoms and molecules in a conductor (except in this case nanoparticles form the lattice!), so some physical and electrical laws should apply to both at the nanometer physical-scale.

Consider a colloid where the particles all have a similar electric charge and are mutually-repulsive. If the concentration of similarly-charged particles is high enough, then the similarly-charged particles will organize into a lattice structure and any lateral motion (or motion whatsoever) of an individual charged-particle in the lattice will affect every other similarly-charged particle in the lattice. Even the slightest motion of a particle in a particular direction will disrupt the total lattice by momentarily altering the arrangement of particles downstream in the direction of motion of the initial particle. Therefore, the interaction of the electric fields of the individual particles in the stream allows an impulse to be sent through the lattice; however, such an impulse can be considered a vibration of the lattice which would normally be considered a phonon! To be more specific, we'll classify the impulse through the lattice as a “phased ballistic phonon” which is a super-elastic interaction of the electric fields of similarly-charged bodies that results in a rather lossless, almost instantaneous transfer of momentum from one point to another in the colloid with very little actual movement of the individual colloidal particles. Compare this action to a row of elastic balls of equal mass where the ball on the end of the row is struck with a ball of equal mass. The ball (with the same mass) at the other end of the row will fly off conserving momentum as each ball in the row interacts. If the process involved super-elastic collisions, then there would be no losses in momentum through the row of balls. Thus, as a logical extension of this idea, a system can be created with similarly-charged particles dispersed in a solution, where the repelling particles are arranged in a lattice structure in the solution or dispersing medium, which will transfer momentum from particle-to-particle without substantial losses due to the super-elastic interaction of particle electric-fields (which is to be known as a “phased ballistic phonon”).

Now, if a donut-shaped, non-conductive container is filled with a great multitude of similarly-charged and repelling conductive particles, the particles will distribute themselves and arrange into a lattice structure in the dispersing medium and inside the container so that the slightest sidewise motion of any particle in the donut-shaped container will result in an impulse, or a phased ballistic phonon, being sent through the lattice and around the donut-shaped container. Moreover, if the particle-concentration in the dispersing medium is great enough and the similar electric-charge of the particles is great enough, then a system for transferring an impulse (phonon) without significant losses is created that depends mostly on the sidewise interaction of the electric fields of a great multitude of particles, and which depends little on the actual motion of the particles themselves. Electric current in a normal conductor is normally characterized by an instantaneous impulse through the conductor with very little electron-drift through the conductor (which is actual electric current in amperes). When an electric field is applied in a conductor, the electrons carry energy and hence they transport both an electrical charge and heat. Actual movement of electrons in a conductor from molecule-to-molecule results in joule heating or I²R losses, but a phased ballistic phonon in a conductor requires only the interaction of particle electric-fields and very little motion (if any) of the particles in the lattice is required. For that matter, if the impulse moves fast enough through the lattice, the mass (inertia) of the individual particles will prevent them from reacting at all since the impulse of electric-fields acts so fast. Suppose now that a magnetic field is introduced very rapidly at one section of the donut-shaped container, which is full of mutually-repulsive, highly-charged particles in sufficient quantity in the dispersing medium to make a continuous ring of particles in the container. The magnetic lines of flux can induce a motion or impulse in the container by interacting with the charged particles to create a phased ballistic phonon that will move around the donut-shaped container with relatively few losses! If an attempt is made to add more energy to the phased ballistic phonon moving inside the container by again applying a moving magnetic field, the procedure must be done properly or a disruption in the particle-to-particle flow will result. In other words, energy must be added so it is perfectly in phase with the moving phased ballistic phonon. Even though the interaction of electric-fields from one particle to the next is very rapid, it will still require a finite amount of time for the phonon to “vibrate” completely around the container. And that is why it's a “phased” ballistic phonon! The cycle of the lattice-vibration, or phased ballistic phonon, which is the time of travel around the container, depends on such things as the physical parameters of the container, particle concentration, and particle size. If the particle-concentration and particle-charge are high enough, then there would come a point where the “vibration” in the lattice flows indefinitely with negligible losses (superconductivity?), which would imply a phonon technically becomes the transport-mechanism for electric-charge—if that's what it really is. It's interesting to note that if energy is continuously added in phase to increase the phased ballistic phonon, tremendously strong magnetic fields can rise around the container and be sustained, but the magnetic field will be of the direct-current type and not the alternating-current type. Finally, the same type of transport-mechanism as described for the present invention can be responsible for the “anomalous” increase in thermal conductivity, on a more limited basis, in the nanofluids of Choi, Withers, and associates.

### DRAWING FIGURES

FIG. 1 shows an enlarged section of either a nanofluid-circuit or a colloidal charged-particle circuit as part of the larger circuits.

FIG. 2 shows a nanofluid-circuit or a colloidal charged-particle circuit along with the means for adding or extracting energy into or from the circuits, respectively. Also shown is a means for energizing or providing electric charges to the nanoparticles in a colloidal charged-particle circuit.

### DRAWINGS—REFERENCE NUMERALS

1. nanoparticle
2. dispersing medium
3. container
4. colloidal charged-particle circuit or nanofluid-circuit
5. means for adding energy to a colloidal charged-particle circuit or a nanofluid-circuit
6. means for extracting energy from a colloidal charged-particle circuit or a nanofluid-circuit
7. means for energizing highly-charged, mutually-repulsive particles

### DETAILED DESCRIPTION OF THE DRAWING FIGURES

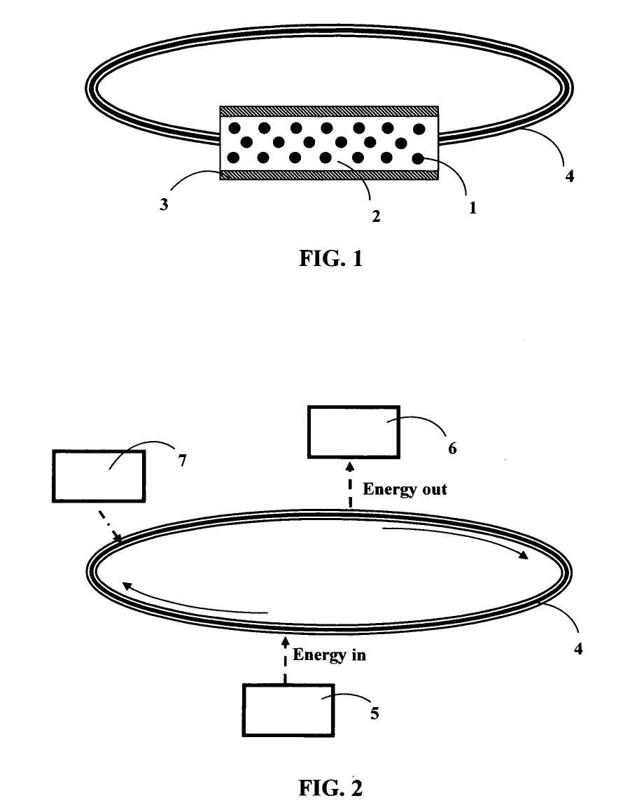

FIG. 1 illustrates a section of a nanofluid-circuit that is comprised of a nanofluid that exhibits both high thermal conductivity (as disclosed in the patent specifications of Choi et al. and Withers et al.) and possibly high electrical conductivity, such as carbon nanotubes or copper nanocrystalline particles dispersed in a glycol mixture, where the particles dispersed in the nanofluid are by nature, electrically-charged due to their ionic characteristics and dipolar attributes, and that may or may not exhibit a zeta potential and a diffuse double-layer. Or, it could also illustrate a section of a colloidal charged-particle circuit comprised of a great multitude of highly-charged, mutually-repulsive conductive particles, such as copper microspheres or carbon nanotubes, that have been given an electrical charge “artificially” or in a way where the electric-charge would not occur naturally, and are dispersed in a gaseous, liquid, or solid dispersing medium. Both types of circuit are designed for exploiting the characteristics of continuous, phased lattice-vibrations known as a phased ballistic phonon. A phased ballistic phonon by definition is a continuous particle-to-particle vibration through a lattice-arrangement of particles due to the interaction of the electric-fields of the particles or the electron-clouds of the atoms of the particles, which are arranged in a lattice structure inside a dispersing medium, where the particles are of any size, shape, or type of matter, and where the particles have a similar electric charge and are mutually-repulsive. The phased ballistic phonon has both frequency and wavelength aspects that depend on physical parameters of the container holding the nanofluid or other type of colloid, the concentration of particles in the dispersing medium, the size or shape of the dispersed particles, and the material type and composition of the dispersed particles. However, the “cycle” of the phased ballistic phonon does not include a change of flow-direction. The flow is always in the same direction in a nanofluid-circuit or a colloidal charged-particle circuit as described herein. FIG. 2 shows a nanofluid-circuit or a colloidal charged-particle circuit comprised of sections of the circuit (shown in FIG. 1) either comprised of a nanofluid that exhibits high thermal conductivity, such as carbon nanotubes dispersed in a glycol mixture, or else of sections of circuit (also shown in FIG. 1) of a colloidal-system comprised of a great multitude of conductive particles, such as copper microspheres or carbon nanotubes, dispersed in a solid, liquid, or gaseous dispersing medium. Also shown in FIG. 2 is a means for adding electric energy to the nanofluid-circuit or the colloidal charged-particle circuit and a means for extracting electric energy from the circuits Another means is added for energizing the highly-charged, mutually-repulsive nanoparticles in a colloidal charged-particle circuit.

### Operation

In FIG. 1, a section of a nanofluid-circuit 4 is shown in a static condition where the nanoparticles 1 have arranged into a lattice structure in the dispersing medium 2 inside the container 3 due to the mutually-repulsive effect of their ionic characteristics, dipolar attributes, or some interaction due to a zeta potential and a diffuse double-layer of each nanoparticle 1 (or the electron-clouds of atoms in the nanoparticles). Any slight motion of any nanoparticle 1 in the nanofluid-circuit 4 will cause an almost lossless impulse, whether electrical or physical in nature, to travel around and through the nanofluid-circuit 4 as the electric fields of the nanoparticles 1 in the nanofluid-circuit 4 interact. FIG. 1 can also illustrate a section of a colloidal charged-particle circuit 4 that is in a static condition where the highly-charged, mutually-repulsive nanoparticles 1 have arranged into a lattice structure in the dispersing medium 2 in the container 3. Any slight motion of any nanoparticle 1 in the colloidal charged-particle circuit 4 will cause a motion, vibration, or phased ballistic phonon moving, vibrating, or flowing from nanoparticle-to-nanoparticle or through a stream of electron-clouds in the atoms comprising the nanoparticles, to travel around and through the charged-particle circuit 4 as the electric fields of the nanoparticles 1 in the charged-particle circuit 4 interact.

In FIG. 2, a means for adding energy to a nanofluid-circuit or a colloidal charged-particle circuit 5 is shown. The means for adding energy 5 is comprised of components capable of inducing an electric, magnetic, or electromagnetic disruption or field into the nanofluid-circuit 4 or the colloidal charged-particle circuit 4 causing an impulse, vibration, or what is termed as a phased ballistic phonon, to travel around and through the nanoparticle circuit 4 or the colloidal charged-particle circuit 4 for relatively long periods of time with negligible losses. A means for extracting energy from a nanofluid-circuit or a colloidal charged-particle circuit 6 is also shown. The means for extracting energy 6 is comprised of components capable of interacting electrically, magnetically, or electromagnetically with the nanoparticles 1 in the nanofluid-circuit 4 or the colloidal charged-particle circuit 4 when an impulse, vibration, or what is termed as a phased ballistic phonon, is moving from nanoparticle-to-nanoparticle with negligible losses in either type of circuit. Also shown in FIG. 2 is a means for energizing highly-charged, mutually-repulsive particles 7 that is comprised of components capable of electrical charges for “artificially” energizing the nanoparticles 1 in a colloidal charged-particle circuit 4.

### CONCLUSIONS, RAMIFICATIONS, AND SCOPE

Accordingly, the reader will see the nanofluid-circuit and the colloidal charged-particle circuit both can provide an electrical path for an electric current with minimal or zero electrical resistance. It should be emphasized that the main difference between a nanofluid-circuit and a colloidal charged-particle circuit is that the nanoparticles in a nanofluid-circuit acquire a “natural” electric charge through some charge-producing mechanism inherent in the nanofluid or in nature. The nanoparticles in a colloidal charged-particle circuit, on the other hand, acquire an electric charge that is “artificially” induced by some man-made charge-producing mechanism that otherwise is not present or inherent in the nanofluid. Moreover, anomalous high thermal conductivity and high electrical conductivity in a nanofluid-circuit can also be the result of a motion, vibration, or a phased ballistic phonon moving, flowing or vibrating somehow through and between the natural atomic electron-clouds or electron-shells of the atoms comprising the nanoparticles in the nanofluid, rather than simply from charged-particle to charged-particle in the nanofluid. And of course, the same mechanism can act as a central or complementary mechanism for electric-charge and heat transfer in the colloid comprising the colloidal charged-particle circuit. Strong electromagnets can be created requiring a minimal amount of electric energy—especially if the container that contains the nanofluid or colloid is in the form of a coil, and electric energy can be stored for long periods of time with few losses. Furthermore, nanofluid-circuits and colloidal charged-particle circuits also provide the additional advantages of:
1. permitting the making of efficient electric generators;
2. permitting the making of very powerful electric motors;
3. allowing electric power to be transmitted long distances with negligible losses;
4. allowing our country to be less dependent on foreign oil;
5. increasing the national security of our country.

Although the description above contains much specificity, this should not be construed as limiting the scope of the invention, but as merely providing illustrations of the presently preferred embodiments of this invention. There are many conceivable embodiments of the present invention that have not been illustrated, but which will surely become obvious to a person skilled in the art, and which will undoubtedly be encompassed by the present invention. Thus, the scope of this invention should be determined by the appended claims and their legal equivalents, rather than by the examples given.

I claim:

1. A nanofluid-circuit that exhibits low electrical resistance or is superconductive, comprising:
a. a nanofluid exhibiting high electrical conductivity and possibly high thermal conductivity comprised of a great multitude of mutually-repulsive nanoparticles of any size or shape and comprised of any type of matter, where each said nanoparticle exhibits an electric-charge due to its natural ionic characteristics, dipolar attributes, or some other natural electric charge-producing mechanism, dispersed in a gaseous, liquid, or solid dispersing medium for keeping said great multitude of mutually-repulsive nanoparticles from settling, or where said nanofluid exhibits said high electrical conductivity and said possibly high thermal conductivity, but where each said nanoparticle in said nanofluid has no natural external said electric-charge, but said high electrical conductivity or said possibly high thermal conductivity is instead caused by a motion, vibration, or phased ballistic phonon moving, vibrating, or flowing through the atomic electron-clouds of atoms comprising said nanoparticles in said nanofluid, and
b. a container of any size or shape, such as a coil, and comprised of any type of matter for containing said nanofluid, and
c. a means for adding energy to said nanofluid for causing a lossless impulse, vibration, or phased ballistic phonon to move, vibrate, or flow in said nanofluid, where said impulse, vibration, or phased ballistic phonon occurs as a series of electrical or physical interactions between said nanoparticles in said nanofluid for relatively long periods of time, and
d. a means for extracting energy from said nanofluid in said container with said lossless impulse, vibration, or phased ballistic phonon already moving, vibrating, or flowing in said nanofluid, and for then applying said energy extracted from said nanofluid to an electrical load device for doing work,
whereby electric energy can be transferred, transmitted, stored, or otherwise used very efficiently and effectively with very few losses.

2. A colloidal charged-particle circuit that exhibits low electrical resistance or is superconductive, comprising:
a. a highly-conductive colloid comprised of a great multitude of electrically-charged, mutually-repulsive conductive nanoparticles of any size or shape, and comprised of any type of matter, dispersed in a gaseous, liquid, or solid dispersing medium for keeping said great multitude of highly-charged, mutually-repulsive nanoparticles from settling, and where said colloid may also exhibit high electrical conductivity and possibly high thermal conductivity resulting from some additional contribution of the interaction of atomic electron-clouds of atoms comprising said nanoparticles in said colloid, and
b. a container of any size or shape, such as a coil, and comprised of any type of matter for containing said colloid, and
c. a means for adding energy to said colloid for causing a lossless impulse, vibration, or phased ballistic phonon to move, vibrate, or flow in said colloid, where said impulse, vibration, or phased ballistic phonon occur as a series of electrical or physical interactions between said nanoparticles in said colloid for relatively long periods of time, and
d. a means for extracting energy from said colloid with said lossless impulse, vibration, or phased ballistic phonon already moving, vibrating, or flowing and for then applying said energy extracted from said colloid to an electrical load device for doing work, and
e. a means for artificially supplying electric charges for energizing said great multitude of highly-charged, mutually-repulsive nanoparticles in said colloid in said dispersing medium, where said electric charges are provide by some man-made device or apparatus.
whereby electric energy can be transferred, transmitted, stored, or otherwise used very efficiently and effectively with very few losses.

3. A method of using a nanofluid or a colloid with high electrical conductivity, comprising:
a. providing either a nanofluid-circuit or a colloidal charged-particle circuit, then
b. supplying energy electrically, magnetically, electromagnetically, or by bombardment and interactions of charged or uncharged particles or rays, to a nanofluid in said nanofluid-circuit or to a colloid in said colloidal charged-particle circuit to cause an impulse, vibration, or phased ballistic phonon to move, vibrate, or flow continuously with few losses from one nanoparticle to another in said nanofluid, in said nanofluid-circuit, or in said colloid, in said colloidal charged-particle circuit for a period of time, then
c. extracting energy electrically, magnetically, or electromagnetically from said nanofluid in said nanofluid-circuit or said colloid in said colloidal charged-particle circuit with said impulse, vibration, or phased ballistic phonon already moving, flowing, or vibrating from one said nanoparticle to another in said nanofluid, in said nanofluid-circuit, or in said colloid, in said colloidal charged-particle circuit with few losses, then
d. doing useful work with energy extracted from said impulse, vibration, or phased ballistic phonon already moving, flowing, or vibrating from one said nanoparticle to another in said nanofluid in said nanofluid-circuit or said colloid in said colloidal charged-particle circuit with few losses,
whereby energy is transmitted, transferred, stored, converted, or otherwise used very effectively and efficiently.
